(19) United States
(12) Patent Application Publication
(10) Pub. No.: US 2018/0113032 A1
(43) Pub. Date: Apr. 26, 2018

(54) FLEXIBLE STRETCHABLE CAPACITIVE SENSOR

(71) Applicant: North Carolina State University, Raleigh, NC (US)

(72) Inventors: Michael D. Dickey, Raleigh, NC (US); Christopher B. Cooper, Raleigh, NC (US); Mohammad Rashed Khan, Raleigh, NC (US)

(21) Appl. No.: 15/729,151

(22) Filed: Oct. 10, 2017

Related U.S. Application Data
(60) Provisional application No. 62/406,568, filed on Oct. 11, 2016.

(51) Int. Cl. G01L 1/14; H03K 17/96

(52) U.S. Cl. CPC G01L 1/142; G06F 3/044; H03K 17/962

(57) ABSTRACT

A flexible stretchable sensor, methods of use, and methods of forming the same are disclosed herein. In one implementation, the flexible stretchable sensor comprises a plurality of flexible and stretchable fibers in close proximity to one another, wherein each of the flexible fibers comprises a hollow electrically insulating elastomeric fiber at least partially filled with a flexible and stretchable conductive material and an electrical connector in electrical communication with the flexible and stretchable conductive material, wherein a change in an electrical parameter of at least one of the plurality of flexible and stretchable fibers is used to sense an event associated with the at least one of the plurality of flexible and stretchable fibers.

### CROSS REFERENCE TO RELATED APPLICATION

This application claims priority to and benefit of U.S. Provisional Patent Application No. 62/406,568 filed Oct. 11, 2016, which is fully incorporated by reference and made a part hereof.

### GOVERNMENT SUPPORT CLAUSE

This invention was made with government support under W911QY-14-C-0033 awarded by the US Army Natick Soldier Research, Development and Engineering Center (NSRDEC). The government has certain rights in the invention.

### BACKGROUND

Generally, capacitive sensors are rigid and typically have a sheet-like form. However, there is a desire to have fiber capacitive sensors that are extremely soft, flexible and stretchable, as well as small (˜200-800 μm diameter), which could be used with artificial muscles, soft robotics, clothing, stretchable devices, textiles, wires, and the like.

### SUMMARY

Soft, flexible and stretchable sensors possess the potential to be incorporated into soft robotics as well as wearable, conformable, and deformable electronic devices. Liquid metals and other flexible, stretchable conductive materials represent promising classes of materials for creating these sensors because they can undergo large deformations while retaining electrical continuity. Incorporating liquid metal or other flexible stretchable conductive materials into hollow elastomeric capillaries results in a fiber geometry that has the ability to be integrated with textiles, be compliant over complex surfaces, and be mass produced at high speeds.

Disclosed herein are sensors and methods wherein liquid metal or other flexible stretchable conductive materials are injected into the core of hollow and extremely stretchable elastomeric fibers and the resulting fibers intertwined in a double or triple helix or otherwise place in close proximity to one another to fabricate sensors. Such sensors may be used to measure at least torsion, strain, and touch. Twisting or elongating the fibers changes the geometry and, in turn, electrical parameters of the fibers such as capacitance and resistance, between the conductive cores in a predictable way. These sensors offer a mechanism to measure torsion up to approximately 10,800 rad/m, or greater, which is at least two orders of magnitude higher than current torsion sensors. These intertwined fibers can also sense strain capacitively at 100% and greater. In a complimentary embodiment, hollow fibers are injected with different lengths of conductive core material to create a sensor that distinguishes touch along the length of a bundle of fibers. This sensing mechanism is conceptually similar to commercial capacitive touch screens, but occurs within an extremely stretchable fiber-shaped device.

In one implementation, a flexible and stretchable sensor is disclosed comprising a plurality of flexible and stretchable fibers in close proximity to one another, wherein each of the flexible fibers comprises a hollow electrically insulating elastomeric fiber at least partially filled with a flexible and stretchable conductive material and an electrical connector in electrical communication with the flexible and stretchable conductive material, wherein a change in an electrical parameter of at least one of the plurality of flexible and stretchable fibers is used to sense an event associated with the at least one of the plurality of flexible and stretchable fibers.

Alternatively or optionally, the plurality of flexible and stretchable fibers in close proximity to one another comprises at least two flexible and stretchable fibers twisted together.

Alternatively or optionally, the change in the electrical parameter of the at least one of the plurality of flexible and stretchable fibers comprises a change in capacitance of the at least one of the plurality of flexible and stretchable fibers is used to sense a change in torsion or a change in strain of the at least one of the plurality of flexible and stretchable fibers or the change in capacitance of the at least one of the plurality of flexible and stretchable fibers is used to sense a touch to the at least one of the plurality of flexible and stretchable fibers.

Alternatively or optionally, the change in capacitance of the at least one of the plurality of flexible and stretchable fibers used to sense the change in torsion or the change in strain is caused by a change in a geometry of the at least one of the plurality of flexible and stretchable fibers.

Alternatively or optionally, the change in capacitance of the at least one of the plurality of flexible and stretchable fibers used to sense the touch to the at least one of the plurality of flexible and stretchable fiber is caused by the touch.

Alternatively or optionally, the flexible stretchable sensor can measure torsion up to 10,800 rad/m, or greater.

Alternatively or optionally, the flexible stretchable sensor can measure strain up to a 100 percent or greater increase in length of the plurality of flexible and stretchable fibers in close proximity to one another.

Alternatively or optionally, the plurality of flexible and stretchable fibers in close proximity to one another have a length, said length divided into a plurality of sections, wherein a change in capacitance in one or more of the plurality of flexible and stretchable fibers in close proximity to one another can be used to sense a touch to one or more of the plurality of flexible and stretchable fibers in close proximity to one another and to determine a specific section of the plurality of sections where the touch occurred.

Alternatively or optionally, the at least two flexible and stretchable fibers twisted together have a length, said length divided into at least two sections, wherein a first of the at least two flexible and stretchable fibers twisted together has the flexible and stretchable conductive material in a first and a second section of the at least two sections and a second of the at least two flexible and stretchable fibers twisted together has the flexible and stretchable conductive material in only a first section of the at least two sections and wherein a touch can be sensed and determined to be in the first section by a change in capacitance of the first and the second of the at least two flexible and stretchable fibers twisted together and a touch can be detected and determined to be in the second section by a change in capacitance of the first of the at least two flexible and stretchable fibers twisted together.

Alternatively or optionally, the plurality of flexible and stretchable fibers in close proximity to one another comprise at least three flexible and stretchable fibers twisted together and having a length, said length divided into at least three sections, wherein a first of the at least two flexible and stretchable fibers twisted together has the flexible and stretchable conductive material in a first, a second, and a third section of the at least three sections and a second of the at least three flexible and stretchable fibers twisted together has the flexible and stretchable conductive material in only the first section and the second section of the at least three sections and a third of the at least three flexible and stretchable fibers twisted together has the flexible and stretchable conductive material in only the first section of the at least three sections, wherein a touch can be sensed and determined to be in the first section by a change in capacitance of the first, the second and the third of the at least three flexible and stretchable fibers twisted together and a touch can be detected and determined to be in the second section by a change in capacitance of only the first and the second of the at least three flexible and stretchable fibers twisted together and a touch can be detected and determined to be in the third section by a change in capacitance of only the first of the at least three flexible and stretchable fibers twisted together.

Alternatively or optionally, the plurality of flexible and stretchable fibers each have a triangular cross-section.

Alternatively or optionally, the hollow electrically insulating elastomeric fiber may have a wall thickness of approximately 55 μm to approximately 160 μm and the triangular cross-section may have a side length of approximately 235 μm to approximately 850 μm.

In another implementation, a flexible stretchable strain sensor is described. The strain sensor comprises at least two flexible and stretchable fibers having a length, said fibers helically twisted together substantially throughout the length, wherein each of the flexible fibers comprises a hollow electrically insulating elastomeric fiber at least partially filled with a flexible and stretchable conductive material; and an electrical connector in electrical communication with the flexible and stretchable conductive material, wherein a change in capacitance can be measured at the electrical connector of each of the at least two flexible and stretchable fibers, said change in capacitance caused by a change in strain to at least a portion of the length of the at least two flexible and stretchable fibers.

In another implementation, a flexible stretchable torsion sensor is described. One embodiment of the torsion sensor comprises at least two flexible and stretchable fibers having a length, said fibers helically twisted together substantially throughout the length, wherein each of the flexible fibers comprises a hollow electrically insulating elastomeric fiber at least partially filled with a flexible and stretchable conductive material; and an electrical connector in electrical communication with the flexible and stretchable conductive material, wherein a change in capacitance can be measured at the electrical connector of each of the at least two flexible and stretchable fibers, said change in capacitance caused by a change in torsion to at least a portion of the length of the at least two flexible and stretchable fibers.

In yet another implementation, a flexible stretchable touch sensor is described that comprises at least two flexible and stretchable fibers having a length helically twisted together substantially throughout the length, wherein each of the flexible fibers comprises a hollow electrically insulating elastomeric fiber at least partially filled with a flexible and stretchable conductive material; and an electrical connector in electrical communication with the flexible and stretchable conductive material, wherein said length is divided into at least two sections, wherein a first of the at least two flexible and stretchable fibers twisted together has the flexible and stretchable conductive material in a first and a second section of the at least two sections and a second of the at least two flexible and stretchable fibers twisted together has the flexible and stretchable conductive material in only a first section of the at least two sections and wherein a touch can be sensed and determined to be in the first section by a change in capacitance of the first and the second of the at least two flexible and stretchable fibers twisted together as measured at the electrical connectors of the first and the second of the at least two flexible and stretchable fibers and a touch can be detected and determined to be in the second section by a change in capacitance of the first of the at least two flexible and stretchable fibers twisted together as measured at the electrical connector of the first of the at least two flexible and stretchable fibers.

In a further implementation, a method of capacitive sensing is described comprising providing a plurality of flexible and stretchable fibers in close proximity to one another, said plurality of flexible and stretchable fibers having a length, wherein each of the flexible fibers comprises a hollow electrically insulating elastomeric fiber at least partially filled with a flexible and stretchable conductive material and an electrical connector in electrical communication with the flexible and stretchable conductive material; and sensing a change in capacitance of at least one of the plurality of flexible and stretchable fibers in close proximity to one another, wherein the change in capacitance is cause by at least one of a change in torsion to at least a portion of the length of the at least one of the plurality of flexible and stretchable fibers, a change in strain to at least a portion of the length of the at least one of the plurality of flexible and stretchable fibers, or at touch to at least one of the plurality of flexible and stretchable fibers.

In another implementation, a method of sensing strain using a flexible stretchable strain sensor is described comprising providing at least two flexible and stretchable fibers having a length; helically twisting the at least two flexible and stretchable fibers together substantially throughout the length, wherein each of the flexible fibers comprises a hollow electrically insulating elastomeric fiber at least partially filled with a flexible and stretchable conductive material, and an electrical connector in electrical communication with the flexible and stretchable conductive material; and detecting, at the electrical connectors of each of the at least two flexible and stretchable fibers, a change in capacitance caused by a change in strain to at least a portion of the length of the at least two flexible and stretchable fibers.

Yet another implementation discloses a method of sensing torsion using a flexible stretchable strain sensor, comprising providing at least two flexible and stretchable fibers having a length; helically twisting the at least two flexible and stretchable fibers together substantially throughout the length, wherein each of the flexible fibers comprises a hollow electrically insulating elastomeric fiber at least partially filled with a flexible and stretchable conductive material, and an electrical connector in electrical communication with the flexible and stretchable conductive material; and detecting, at the electrical connectors of each of the at least two flexible and stretchable fibers, a change in capacitance caused by a change in torsion to at least a portion of the length of the at least two flexible and stretchable fibers.

A further implementation discloses a method of sensing touch using a flexible stretchable touch sensor, comprising providing at least two flexible and stretchable fibers having a length helically twisted together substantially throughout the length, wherein each of the flexible fibers comprises a hollow electrically insulating elastomeric fiber at least partially filled with a flexible and stretchable conductive material, and an electrical connector in electrical communication with the flexible and stretchable conductive material; dividing said length into at least two sections, wherein a first of the at least two flexible and stretchable fibers twisted together has the flexible and stretchable conductive material in a first and a second section of the at least two sections and a second of the at least two flexible and stretchable fibers twisted together has the flexible and stretchable conductive material in only a first section of the at least two sections; and sensing a touch and determining the touch is in the first section by measuring a change in capacitance of both the first and the second of the at least two flexible and stretchable fibers twisted together; or sensing the touch and determining the touch is in the second section by measuring a change in capacitance of only the first of the at least two flexible and stretchable fibers twisted together.

Further disclosed herein is a method of fabricating a flexible stretchable sensor comprising forming a plurality of flexible and stretchable hollow fibers by melt-extruding an elastomeric polymer through a die, into a water bath and onto a collection roll; injecting a flexible and stretchable conductive material into the plurality of flexible and stretchable hollow fibers with a needle-tipped syringe such that the plurality of flexible and stretchable hollow fibers are at least partially filled with the flexible and stretchable conductive material; inserting an electrical connector into at least one end of the plurality of flexible and stretchable hollow fibers such that the electrical connector is in electrical communication with the flexible and stretchable conductive material; and helically twisting together at least two of the plurality of flexible and stretchable hollow fibers that are at least partially filled with the flexible and stretchable conductive material. Other fabrication methods may include injection molding of the fibers.

Alternatively or optionally, the elastomeric polymer may comprise Hytrel™ H63, other thermoplastic polymers, and the like.

Alternatively or optionally, the flexible and stretchable conductive material may comprise a liquid metal such as eutectic gallium indium (EGaIn), and the like.

Alternatively or optionally, the flexible and stretchable conductive material may comprise a composite or an elastomer.

Alternatively or optionally, the electrical connector may comprise a copper wire.

Alternatively or optionally, the method of fabrication may include sealing the at least one end of the plurality of flexible and stretchable hollow fibers with an adhesive sealant.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The following detailed description will be better understood when read in conjunction with the appended drawings, in which there is shown one or more of the multiple embodiments of the present disclosure. It should be understood, however, that the various embodiments of the present disclosure are not limited to the precise arrangements and instrumentalities shown in the drawings:

FIG. 1A shows a photograph of two fibers (850 μm in diameter) twisted to an initial torsion of 630 rad/m;

FIG. 1B is an image of a (triangular) cross-section of one of the fibers shown in FIG. 1A;

FIGS. 1C and 1D show images of the fibers shown in FIGS. 1A and 1B being stretched to 150% strain and twisted to 1,260 rad/m, respectively;

FIG. 2A plots the change in capacitance per length (end-to-end length of the fiber) as a function of torsional level;

FIG. 2B plots the change in capacitance per contact area as a function of torsional level for all three diameter fibers along with the resulting regression line;

FIG. 2C plots the change in capacitance per length for a pair of 850 μm diameter intertwined fibers that were twisted and untwisted for the first six cycles;

FIG. 3A plots the capacitance per initial length as a function of percentage strain for a pair of 850 μm diameter fibers at different torsional levels and their respective regression lines;

FIGS. 3B-D compare the predicted values from Equation (12) to the experimental change in capacitance per length as a function of percentage strain for three different torsional levels (314 rad/m, 942 rad/m and 1571 rad/m respectively);

FIG. 4A depicts three fibers filled to different lengths with a flexible stretchable conductive core material such as EGaIn;

FIG. 4B is an image showing a finger touching each region, which is detected by the sensor and results in the illumination of the corresponding LED light;

FIG. 4C shows a graph of capacitance as a function of time for a fully filled, two-thirds filled, and one-third filled fiber as blue 408, red 410, and green 412 lines, respectively; and

FIG. 4D plots capacitance versus time for a single fiber as it undergoes rapid tapping in 100 ms intervals, showing that the fiber can respond rapidly to touch.

### DETAILED DESCRIPTION

Before the present methods and systems are disclosed and described, it is to be understood that the methods and systems are not limited to specific synthetic methods, specific components, or to particular compositions. It is also to be understood that the terminology used herein is for the purpose of describing particular embodiments only and is not intended to be limiting.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another embodiment includes—from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal embodiment. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods.

The present methods and systems may be understood more readily by reference to the following detailed description of preferred embodiments and the Examples included therein and to the Figures and their previous and following description.

Described herein are embodiments of sensors comprising stretchable hollow elastomeric fibers at least partially filled with flexible stretchable conductive material such as liquid metal (LM) as soft, flexible and stretchable capacitive sensors of torsion, strain, and touch. Sensors that are soft and stretchable are useful for soft robotics as well as wearable, conformable, and deformable electronic devices.

In one embodiment, the flexible stretchable conductive material placed within the hollow elastomeric fibers comprises liquid metals, compounds, conductive elastomers, conductive composites (e.g. Ag particles in elastomer, or carbon in elastomer), and the like. LMs, such as eutectic gallium indium (EGaIn, 75% Ga and 25% In), offer a promising way to create such sensors. Advantageously, EGaIn has low toxicity, negligible vapor pressure at room temperature, and low viscosity. The latter property allows LM to flow in response to deformation, whereas solid metals are stiff and prone to fail at small strains. Embedding LMs in elastomers decouples the electrical and mechanical properties; that is, these composites have the electrical properties of the metal and the mechanical properties of the elastomer. Incorporating the LM into the hollow core of an elastomeric fiber results in a useful final fiber geometry for sensors because fibers may be integrated into clothing and fabrics. Furthermore, fibers are inherently flexible, compliant, and conformal due to their narrow cross section. As a result, fibers can readily wrap onto and conform to surfaces with Gaussian curvature whereas 2D sheets cannot without significant deformation. Fibers can also be mass produced at high speeds with small diameters (hundreds of microns) and produced by hand in a laboratory environment at room temperature. The fibers described herein are advantageously built from stretchable and soft materials. As used herein, “fiber” includes a single fiber with a single conductive core, a single fiber with multiple conductive cores, or multiple fibers bonded together with multiple conductive cores.

The embodiments described herein can be used for capacitive sensing of torsion, strain, and touch while maintaining a fiber shape; that is, without weaving the fibers into a fabric or encasing them in other materials. It is possible to sense both torsion and strain because twisting or stretching two intertwined fibers increases the contact area between them, and therefore alters the capacitance. The complexity of torsion, which causes both normal and shear strain, has previously precluded the development of a simple sensor capable of measuring a large range of torsion. Current torsion sensors measure changes in normalized resistance, pressure, and optical properties, or utilize surface acoustic waves or the inverse magnetostrictive effect. Some of these sensors can detect changes as small as 0.3 rad/m and can measure torsion up to 800 rad/m before failure. Most current torsion sensors, however, are rigid, cumbersome, expensive, and complex. The soft and stretchable sensor disclosed herein offers a simple mechanism to measure large changes in torsion, which may be useful for unconventional robotics, artificial muscle, and the like.

In addition to sensing torsion, intertwined fibers increase capacitance in response to strain due to the increase in contact area from elongation. There is growing interest in stretchable sensors capable of measuring large strains (above 30%) relative to conventional strain sensors. Most existing stretchable strain sensors measure resistance or capacitance; the latter occurs due to mechanical deformations that decrease the distance between electrodes or increase the electrode area. Capacitive strain sensors offer gauge factors (from 0.004 to 1) that do not vary over large ranges of strains (from 35 to 300%), and thus offer a promising mechanism to create stretchable strain sensors.

Intertwined fibers or fibers in close proximity with flexible stretchable conductive cores also offer the opportunity to sense touch using capacitance. Capacitance is a commonly used measurement for many touch sensors including commercial touch screens, and previously it has been utilized to create soft touch sensors. Such sensors have final geometries of pads or woven fiber grids, but a capacitive touch sensor that can differentiate touch along its length has yet to be implemented in a strictly fiber shape or using hyper-elastic materials.

Disclosed and described herein are capacitive sensors for detecting torsion, touch, and strain. Generally, the sensors are comprised of elastomeric polymer fibers that may be intertwined or otherwise in close proximity to one another having flexible conductive cores throughout at least a portion of the fiber. The described embodiments are advantageous in that they have the ability to detect changes in torsion up to 10,800 rad/m (i.e., two orders of magnitude higher than current torsion sensors), or greater; the simplicity of the capacitive sensing mechanism for measuring torsion, strain, and touch; the fabrication of a fiber capable of differentiating touch along its length; the versatile fiber shape; and, the soft and stretchable mechanical properties of the sensor.

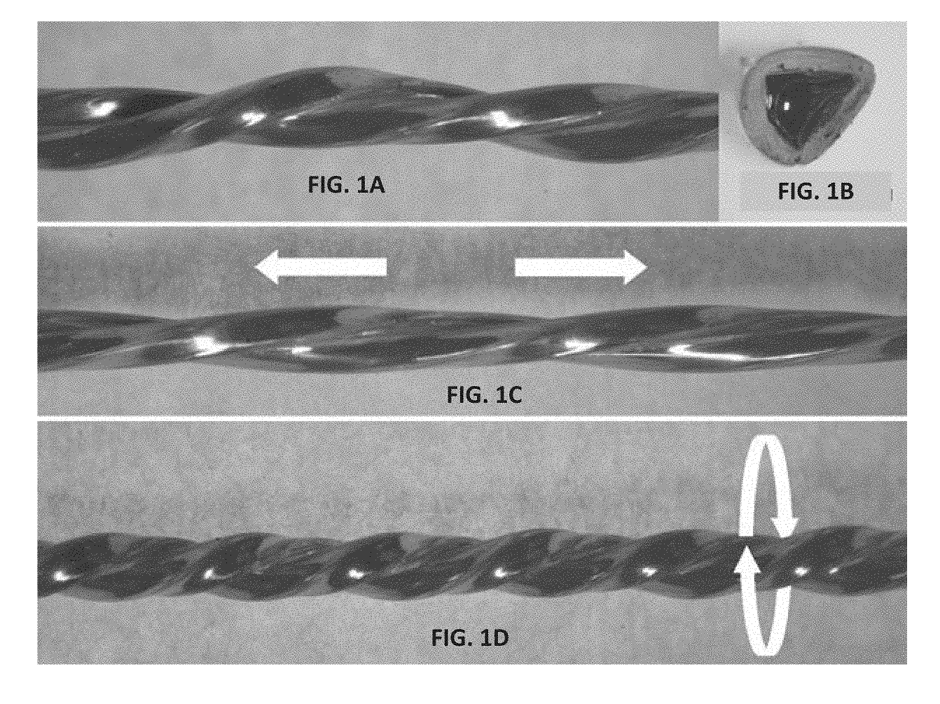

FIG. 1A shows a photograph of two fibers (850 μm in diameter) twisted to an initial torsion of 630 rad/m. FIG. 1B is an image of a (triangular) cross-section of one of the fibers shown in FIG. 1A. Images of the fibers shown in FIGS. 1A and 1B being stretched to 150% strain and twisted to 1,260 rad/m are shown in FIGS. 1C and 1D, respectively. Stretching the fibers to 150% strain reduces the torsional level to 420 rad/m. Additional twisting increases the torsional level to 1,260 rad/m. In one aspect, a method of fabricating a flexible stretchable sensor as shown in FIGS. 1A-1D comprises melt-extruding Hytrel′ H63 through a die, into a water bath, and onto a collection roll using a process such as that described in S. Zhu, J.-H. So, R. Mays, S. Desai, W. R. Barnes, B. Pourdeyhimi, M. D. Dickey, Adv. Funct. Mater. 2013, 23, 2308, which is fully incorporated by reference. The fibers pictured in FIGS. 1A-1D have a triangular cross section with wall thickness of ˜160 μm and side length of ˜850 μm. Other fibers can have different cross-section shapes and/or sizes. For example, fibers having triangular cross sections and wall thicknesses of ˜70 and ˜55 μm and side lengths of ˜350 and ˜235 μm, respectively are contemplated within the scope of embodiments of this disclosure. Therefore, triangular cross-sectional fibers having side lengths of approximately 235 μm to approximately 850 μm are contemplated within the scope of this disclosure. Also, triangular cross-sectional fibers having wall thicknesses of approximately 55 μm to approximately 160 μm are also contemplated within the scope of this disclosure. Other fibers may have different cross-section shapes and wall thicknesses. Although other cross sectional shapes are contemplated within the scope of this disclosure, triangular cross sections have been shown previously to minimize non-linearity and hysteresis in pressure sensing using elastomeric channels filled with LM (see Y.-L. Park, D. Tepayotl-Ramirez, R. J. Wood, C. Majidi, Appl. Phys. Lett. 2012, 101, 191904, which is fully incorporated by reference). Returning to the described fabrication process, a conductive, flexible stretchable material was injected into the hollow fibers, at least partially filling the fibers. For example, EGaIn can be injected into the hollow fibers with a needle-tipped syringe. Additionally, copper wire, used as an electrical connector, can be inserted into at least one end of the fiber to be in electrical communication with the conductive flexible stretchable core material. The connection between the copper wire and the core material may be sealed using an adhesive sealant (e.g., Norland NOA 61).

In one aspect, a flexible stretchable torsion sensor is disclosed. An embodiment of the torsion sensor comprises at least two flexible and stretchable fibers having a length. The fibers are helically twisted together or otherwise in close proximity substantially throughout the length, wherein each of the flexible fibers comprises a hollow electrically insulating elastomeric fiber at least partially filled with a flexible and stretchable conductive material; and an electrical connector in electrical communication with the flexible and stretchable conductive material. When torsion is applied to the fibers, a change in an electrical parameter (e.g., capacitance, resistance, etc.) of the fibers occurs. Such a change can be measured with a meter and used to determine the torsion applied to the fibers. For example, one or more capacitance meters may be used to measure a change in capacitance of the fibers caused by the application of torsion to the fibers. The one or more capacitance meters connect to the electrical connector of each of the at least two flexible and stretchable fibers and measure a change in capacitance caused by a change in torsion to at least a portion of the length of the at least two flexible and stretchable fibers.

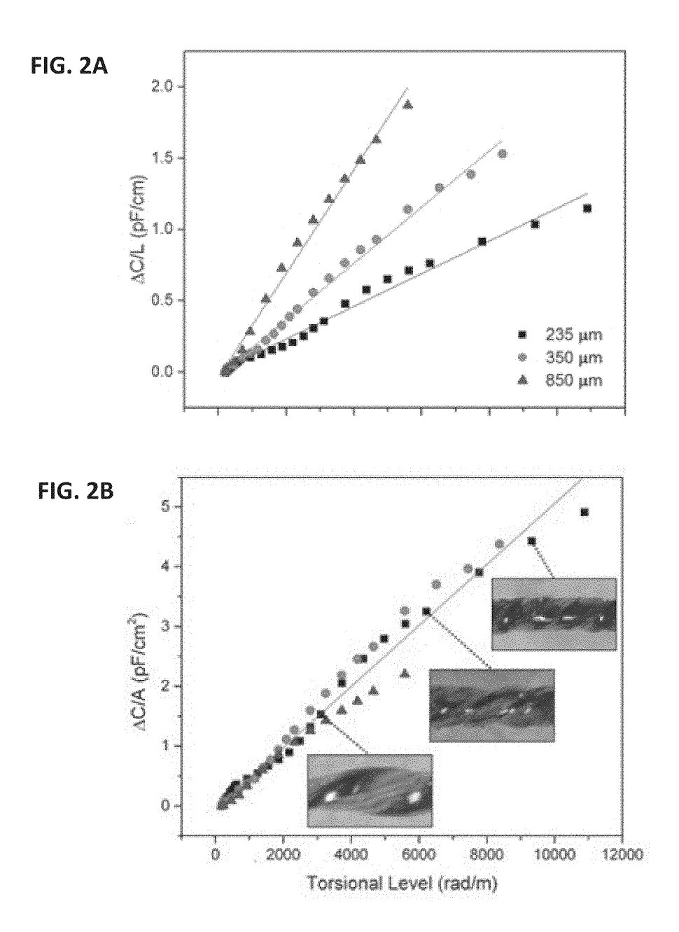

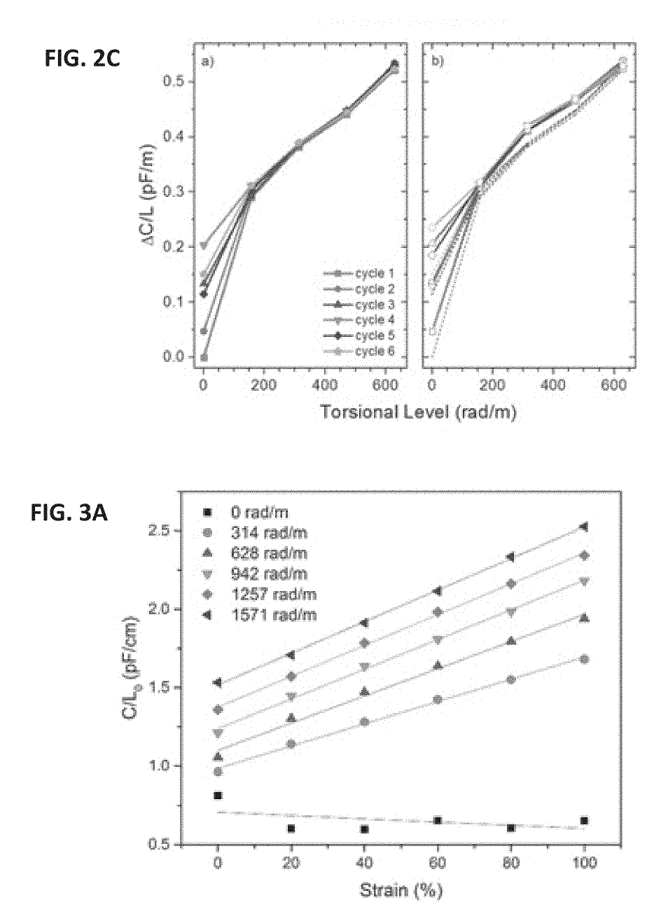

In an example of the ability to measure change in capacitance caused by a change in torsion, the change in capacitance between two fibers was measured after incrementally twisting them, and during the measurement a constant end-to-end length was maintained (i.e., keeping strain at 0%). FIG. 2A plots the change in capacitance per length (end-to-end length of the fiber) as a function of torsional level. The torsional level is the number of radians (from twisting) normalized by the end-to-end length. For example, one full twist (2π) would have a torsional level of ˜60 rad/m for a 10 cm fiber bundle. The plot of FIG. 2A includes data for pairs of intertwined fibers with three different outer diameters and their respective regression lines. The change in capacitance per length is reported relative to the value at 200 rad/m. 200 rad/m was used as a reference rather than 0 rad/m because the capacitance is highly variable at 0 rad/m since there is no tension holding the fibers together. Calculating the change in capacitance has the additional benefit of removing any stray capacitance effects from the copper wires or leads, since they remain constant throughout the experiment.

The change in capacitance per length varies linearly with the torsional level. The slopes of the best fit are (1.15±0.03)×10⁻⁴, (1.97±0.04)×10⁻⁴, and

$$( 3.64 \pm 0.11 ) \times {10}^{- 4} \frac{pF \text{/} cm}{rad \text{/} m}$$

for 235, 350, and 850 μm diameter fibers, respectively, which shows that the change in capacitance for a given change in torsional level increases as fiber diameter increases. FIG. 2B shows that capacitance change per length normalized by the diameter of the fibers collapses the data onto a regression line. All three regressions have an R² value of 0.99. Any nonlinearities fall within the standard error of the measurements. Detection limits (i.e. detecting rad/m from measurements of pF/cm) for each sensor were determined by calculating the standard error for a single observation to create a 95% confidence interval in pF/cm. Using the slope found by the regression, this interval was converted into rad/m to find detection limits of 609, 355, and 302 rad/m for the 235, 350, and 850 μm diameter fibers, respectively. A detection limit of 302 rad/m, for example, implies the ability to sense a change in torsional level after five complete twists (for a fiber 10 cm long).

These results demonstrate that the diameter of the fibers influences capacitive sensing. Fibers with a larger diameter may have improved sensitivity; however, fibers with a smaller diameter can sense a larger range of torsion. This result is intuitive: all things otherwise being equal, fibers with larger diameters have to travel a longer physical path when twisted. Because the end-to-end distances of the fiber bundles are held constant, the larger diameter fibers are therefore under more stress at a given torsional level and therefore fibers with smaller diameters can sense a larger range of torsion before mechanical failure. On the other hand, the larger diameter fibers experience a larger change in capacitance with each additional twist, since the amount of additional stress (and thus deformation) is higher, and therefore larger diameter fibers have better sensitivity (or lower detection limits). The maximum value of torsion measured by each type of fiber was 10,887, 8,378, and 5,585 rad/m for the 235, 350, and 850 μm diameter fibers, respectively. These torsional levels are one to two orders of magnitude larger than previously reported torsion sensors, which is attributed to the soft and deformable nature of the materials employed here.

FIG. 2C shows a pair of fibers that are repeatedly twisted and untwisted. The left graph shows the increasing torsion values for each cycle with closed markers. The right graph shows the decreasing torsion values with open markers and the increasing torsion values with solid lines for each cycle.

To understand and validate the results, a quantitative model was developed that describes the capacitance of the fibers as a function of their torsional level. Since the fiber shape deforms during twisting, the triangular cross section can be roughly approximated by a circle. Additionally, the distance between the fiber centers is roughly equivalent to the diameter of the fibers. Thus, the capacitance between two fibers can be modeled using the equation for the capacitance, C, between two long cylindrical wires.

$$\frac{C}{ζ} = \frac{π ɛ}{ln ( \frac{d}{2 δ} + \sqrt{\frac{{d}^{2}}{4 {δ}^{2}} - 1} )} \qquad ( 1 )$$

The insulated wires are in contact over length (note: when twisted, the two fibers adopt the shape of a double helix and thus is their helical length and is greater than the end to end distance, L, which is constant). In Equation (1), d represents the distance between the center of the two wires (in our case, the diameter of the fibers) and δ represents the radius of the wire (in our case, the radius of the LM inside the fiber).

Next, it was assumed that the outer diameter of a fiber divided by the diameter of the conductive core (e.g., EGaIn) inside is a constant ratio σ (i.e. during twisting and thus, elongation of the fiber, the cross section of the fiber shrinks uniformly).

$$σ = \frac{d}{2 δ} \qquad ( 2 )$$

Consequently, Equation (1) simplifies to:

$$\frac{C}{ζ} = \frac{π ɛ}{ln ( σ + \sqrt{{σ}^{2} - 1} )} = γ \qquad ( 3 )$$

where γ is a constant. Thus, it can be written:

C=γζ (4)

Equation (4) indicates that the capacitance between the two fibers is proportional to the fiber length, which becomes longer during twisting. The length, ζ, of a single fiber in the double helix can be estimated using the equation for the arc length of a single helix, where n is the number of full turns, as shown in Equation (5):

ζ=\sqrt{(πnd)²+L²} (5)

By substituting in for torsional level given by Equation (6):

$$τ = \frac{2 π n}{L} \qquad ( 6 )$$

Equation (5) becomes:

$$ζ = \frac{L}{2} \sqrt{{( τ d )}^{2} + 4} \qquad ( 7 )$$

Combining Equations (4) and (7), results in Equation (8):

$$\frac{C}{L} = \frac{γ}{2} \sqrt{{( τ d )}^{2} + 4} \qquad ( 8 )$$

According to Equation (8), to a first order approximation, the capacitance changes with respect to τ, which is consistent with the linear response reported in FIG. 2A. To determine if the model matched quantitatively, the slopes predicted by Equation (8) for each diameter fiber were compared with the measured slopes of the best fit lines in FIG. 2A. Since the value of the slope depends on γ, the predicted value of γ for each diameter fiber was calculate using Equation (3), assuming a dielectric constant of 4.5. The predicted values of γ are 1.012, 1.179, 1.202 pF/cm, which agree well with the experimental values of 0.91±0.01, 0.80±0.02, and 1.02±0.03 pF/cm for the 235, 350, and 850 μm fibers, respectively. The experimental values of γ come from the measured base capacitance per length values of each diameter fiber at zero torsion. This relationship is predicted by evaluating Equation (8) at zero torsion.

A linear fit of the theoretical capacitance per length and torsional level (by inserting γ into Equation (8) for different torsional values, values given in Table S1) gives slopes of (6.1±0.1)×10⁻⁵, (1.20±0.02)×10⁻⁴, and

$$( 3.70 \pm 0.07 ) \times {10}^{- 4} \frac{pF \text{/} cm}{rad \text{/} m}$$

for the 235, 350, and 850 μm diameter fibers, respectively. The experimental slopes in FIG. 2A agree well with these predicted vales (in the case of the 850 μm fiber, the values are practically identical). This agreement between the theoretical and experimental values of γ and the slopes suggests that the proposed model for twisting the fibers is satisfactory. The experimental slope also approaches the value of the predicted slope as the fiber diameter increases, which likely results from the cross section of larger diameter fibers better resembling the circular cross section used in the model. Additionally, Equation (8) predicts that the model will become more linear when the term (τd)² is much greater than 4 (the other term under the square root).

Other potential sources of error with the estimations from Equation (8) include the removal of void space that occurs at low torsional levels and the creation of capacitance between the wires both perpendicular and parallel to the fiber axis at high torsional levels. Nevertheless, the general linear increase in capacitance as torsional level increases, the measured values of γ, and the measured slopes for each diameter fiber are consistent with the predictions given by Equation (8).

Equation (8) also suggests that the slope of the data plotted in FIG. 2A should be roughly proportional to fiber diameter. Therefore, the data was normalized by dividing the change in capacitance per length by the fiber diameter to give change in capacitance per contact area. FIG. 2B plots the change in capacitance per contact area as a function of torsional level for all three diameter fibers along with the resulting regression line. The data points collapse into a single regression with a slope of (5.10±0.11)×10⁻⁴ pf/cm² and an R² value of 0.99. Images of the 235 μm fibers at 3,110, 6,221, and 9,332 rad/m are shown as insets in FIG. 2B (1 mm of length shown).

The performance of the fibers after multiple cycles of twisting and untwisting was explored. FIG. 2C plots the change in capacitance per length for a pair of 850 μm diameter intertwined fibers that were twisted and untwisted for the first six cycles. A large amount of variation occurs at low torsional levels due to the different air gaps that appear between the fibers after each cycle at zero torsion, which arbitrarily changes the contact area and thereby capacitance. Additionally, since the fiber cross sections are not perfect circles, changes in the orientation of the fiber occur at low torsional levels and create corner-edge contact between the fibers (which further reduces the capacitance) as opposed to the preferred face-to-face contact (which minimizes the center to center distance of the fibers and maximizes the contact area) that occurs at higher torsional levels. After a torsional level of 200 rad/m and beyond, more consistent behavior between cycles was observed, which indicates a decrease in void spaces and corner-edge contacts. The discrepancy between the increasing and decreasing torsional level may be attributed to a time-dependent hysteresis that occurs as the fibers are untwisted (i.e. it takes a certain amount of time for the untwisted fibers to return to their original state via decompression due to the friction between fibers).

In another aspect, a flexible stretchable strain sensor is disclosed. An embodiment of the flexible stretchable strain sensor comprises at least two flexible and stretchable fibers having a length. The fibers are helically twisted together or otherwise in close proximity substantially throughout the length. Each of the flexible fibers comprises a hollow electrically insulating elastomeric fiber at least partially filled with a flexible and stretchable conductive material; and an electrical connector in electrical communication with the flexible and stretchable conductive material. A meter can be used to connect to the electrical connector of each of the at least two flexible and stretchable fibers and measure a change in an electrical parameter of the fibers caused by a change in strain to at least a portion of the length of the at least two flexible and stretchable fibers. For example, a capacitance meter can be used to measure a change in capacitance caused by strain applied to at least a portion of the length of the at least two flexible and stretchable fibers.

The change in capacitance of the at least two flexible and stretchable fibers caused by the change in the strain to the portion of the length of the at least two flexible and stretchable fibers is caused by a change in a geometry of the at least two flexible and stretchable fibers. For example, the increase in strain may increase a contact area between the two flexible and stretchable fibers, resulting in increased capacitance. In one aspect, strain can be measured up to a 100 percent increase in the length, or greater, of the at least two flexible and stretchable fibers.

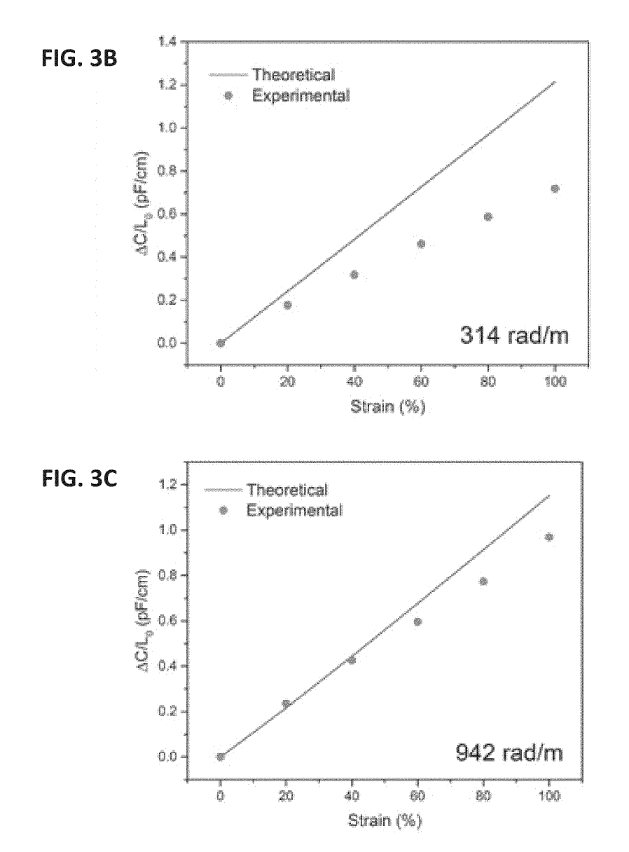

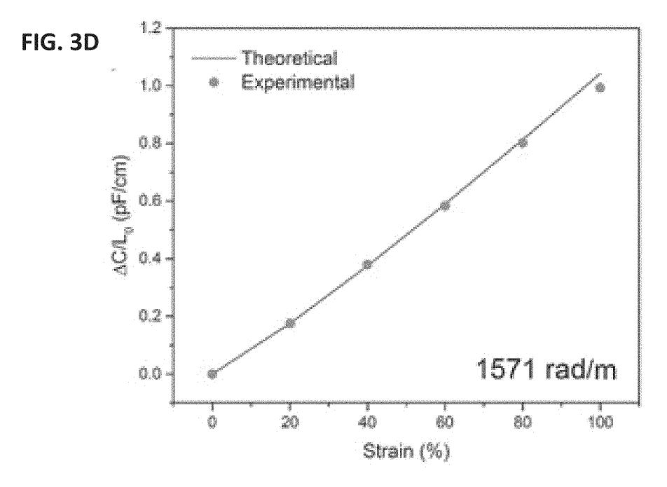

In an example of the ability to measure change in capacitance caused by a change in strain, two fibers were intertwined to a set initial torsional level and then increased the end-to-end length in intervals of 20% while measuring the capacitance. Elongating the fibers increases the contact area between the fibers, resulting in increased capacitance. FIG. 3A plots the capacitance per initial length as a function of percentage strain for a pair of 850 μm diameter fibers at different torsional levels and their respective regression lines. At an initial torsional level of 0 rad/m, there is not a statistically significant relationship between strain and capacitance due to the presence of void space; however, at higher initial torsional levels, the fibers are in intimate contact and a linear relationship emerges. The slopes are (7.1±0.2)×10⁻³, (8.7±0.4)×10⁻³, (9.5±0.2)×10⁻³, (9.8±0.2)×10⁻³, and (1.01±0.01)×10⁻² pF/cm for the initial torsional levels of 314, 628, 942, 1257, and 1571 rad/m, respectively. All of the regressions had an R² value of 0.99. The detection limits were 5.89, 9.45, 5.17, 4.06, and 2.90% of strain, respectively. A gauge factor—the change in signal normalized by strain—was calculated by dividing the change in capacitance by the base capacitance and dividing again by the strain, and was found to be between 0.5 and 0.57 for all initial torsional levels except 0 rad/m.

This linear change can be predicted by adapting Equation (4) to account for the change in capacitance from C₀ to C_{f} due to the change in length from ζ₀ to ζ_{f}:

ΔC=C_{f}−C₀=γ(ζ_{f}−ζ₀) (9)

Using Equations (5) and (9) while noting that the end-to-end length of the fibers is no longer constant, the following equation can be derived:

$$\frac{Δ C}{{L}_{0}} = \frac{γ}{2} [ \sqrt{{( {τ}_{0} d )}^{2} + \frac{4 {L}_{f}^{2}}{{L}_{0}^{2}}} - \sqrt{{( {τ}_{0} {d}_{0} )}^{2} + 4} ] \qquad ( 10 )$$

Assuming a Poisson ratio of 0.5 to conserve volume, d can be substituted with the expression given by Equation (11):

$$d = {{d}_{o} ( \frac{{L}_{o}}{{L}_{f}} )}^{0.5} \qquad ( 11 )$$

Thus, Equation (10) simplifies to:

$$\frac{Δ C}{{L}_{0}} = \frac{γ}{2} [ \sqrt{{( {τ}_{0} {d}_{0} )}^{2} \frac{{L}_{o}}{{L}_{f}} + \frac{4 {L}_{f}^{2}}{{L}_{0}^{2}}} - \sqrt{{( {τ}_{0} {d}_{0} )}^{2} + 4} ] \qquad ( 12 )$$

The parameters in Equation (12) are all constant except for L_{f} and ΔC, which change with elongation. Furthermore, the first term on the right hand side of Equation (12) under the first square root is significantly smaller than the second term at the initial torsional levels tested, and it decreases in size as strain increases. Thus, to a first order approximation, Equation (12) predicts that the change in capacitance will change linearly with respect to elongation (L_{f}). FIGS. 3B-D compare the predicted values from Equation (12) to the experimental change in capacitance per length as a function of percentage strain for three different torsional levels (314 rad/m, 942 rad/m and 1571 rad/m respectively). As the torsional level increases, the agreement between the theoretical Equation (12) and the experimental data improves, perhaps due to the removal of void space and corner-edge contacts between the fibers, for which the theoretical model does not account.

In yet another aspect, a flexible stretchable touch sensor is disclosed. One embodiment of the flexible stretchable touch sensor comprises at least two flexible and stretchable fibers having a length. The fibers are helically twisted together or otherwise in close proximity substantially throughout the length. Each of the stretchable flexible fibers comprises a hollow electrically insulating elastomeric fiber at least partially filled with a flexible and stretchable conductive material; and an electrical connector in electrical communication with the flexible and stretchable conductive material. A meter can be connected to the electrical connector of each of the at least two flexible and stretchable fibers to measure a change in an electrical parameter caused by touching the fibers. The length is divided into at least two sections, wherein a first of the at least two flexible and stretchable fibers twisted together has the flexible and stretchable conductive material in a first and a second section of the at least two sections and a second of the at least two flexible and stretchable fibers twisted together has the flexible and stretchable conductive material in only a first section of the at least two sections. A touch can be sensed and determined to be in the first section by a change in an electrical parameter of the first and the second of the at least two flexible and stretchable fibers twisted together as measured by the one or more meters and a touch can be detected and determined to be in the second section by a change in an electrical parameter of the first of the at least two flexible and stretchable fibers twisted together as measured by the one or more meters. The one or more meters can be sued to measure a change in one or more of capacitance and resistance of the fibers.

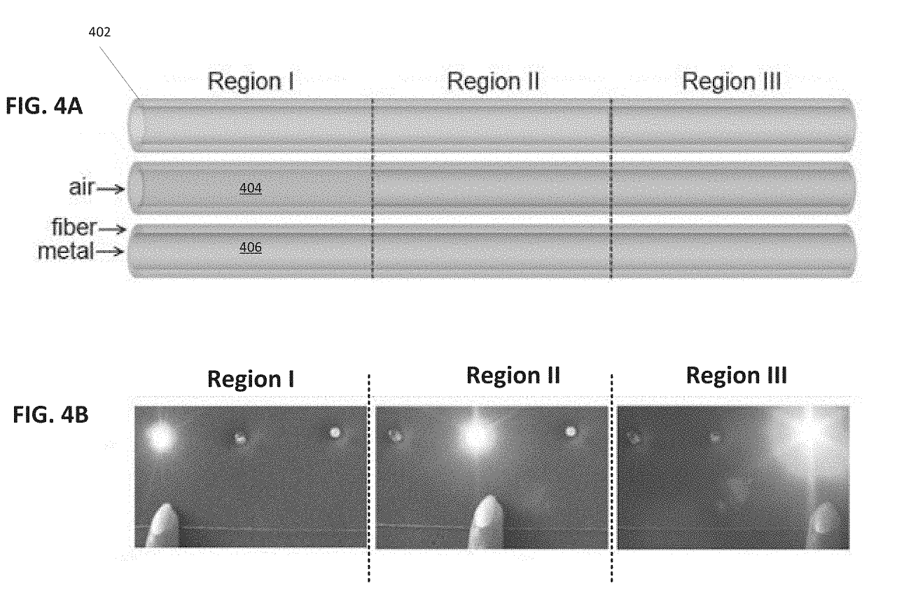

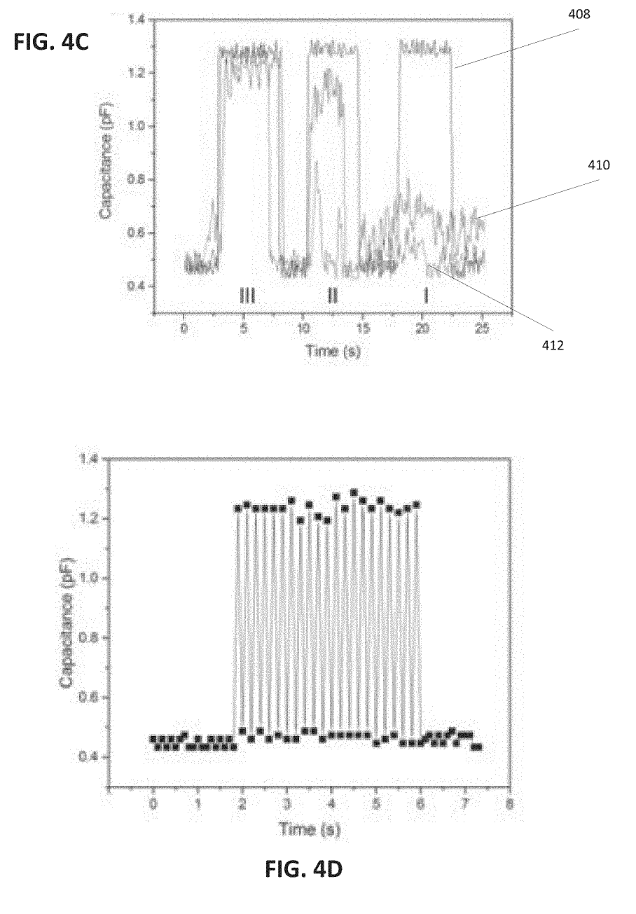

In another aspect, a touch sensor can be fabricated from three intertwined fibers in a triple helix. FIG. 4A depicts three fibers filled to different lengths with a flexible stretchable conductive core material such as EGaIn. The green-colored fiber 402 is filled one-third of the way with the flexible stretchable conductive core material. The red-colored fiber 404 is filled two-thirds of the way, and the blue-colored fiber 406 is fully filled with the flexible stretchable conductive core material. In Region III, all three fibers are filled, while in Regions II and I only two fibers (blue 406 and red 404) and one fiber (blue 406) are filled, respectively. The presence of the flexible stretchable conductive core material in the fiber allows for a capacitor to be formed between the fiber and a touching finger (i.e., self-capacitance). Thus, when a finger touches Region III, all three fibers will report an increase in capacitance since all three contain the flexible stretchable conductive core material in that region, whereas when a finger touches Region I, only the fiber containing the flexible stretchable conductive core material (blue fiber 406) will report an increase in capacitance. FIG. 4B is an image showing a finger touching each region, which is detected by the sensor and results in the illumination of the corresponding LED light. The LEDs and the fibers are connected to a controller such as, for example, an Arduino microcontroller, which reads the change in capacitance from each fiber and sends an output signal to illuminate the correct LED when the appropriate region of the fiber is touched. Touching the fibers may also cause an increase in resistance of the fibers by reducing the area of the fibers, which can be measured.

FIG. 4C shows a graph of capacitance as a function of time for a fully filled, two-thirds filled, and one-third filled fiber as blue 408, red 410, and green 412 lines, respectively. Examination of the graph allows one to clearly identify Region III (where all three lines show an increase in capacitance), Region II (where only the blue and red lines show an increase in capacitance), and Region I (where only the blue line shows an increase in capacitance). The change in capacitance is ˜0.8 pF, slightly less than the 2 pF change measured in conventional touch screens. There is additional variance in the red and green lines compared to the blue lines, most likely due to the stray capacitance and edge effects that occur since these fibers are not completely filled. This variance, however, does not prevent the sensor from distinguishing between the different regions. FIG. 4D plots capacitance versus time for a single fiber as it undergoes rapid tapping in 100 ms intervals, showing that the fiber can respond rapidly to touch.

Described herein is the fabrication and characterization of soft and stretchable capacitive sensors of torsion, strain, and touch using hollow elastomeric fibers filled with a flexible stretchable conductive core material such as a LM (e.g. EGaIn). Twisting or elongating an intertwined bundle of two fibers increases the contact area between the fibers and therefore the capacitance. Additionally, fibers filled with a flexible stretchable conductive core material can serve as capacitive touch sensors along the length of a fiber bundle. Because these fiber sensors are extremely soft and stretchable, as well as small (˜200-800 μm diameter), they could be used with artificial muscles, soft robotics, stretchable devices, clothing (woven and wearable sensors in stretchable textiles for a variety of sensing functions), and the like. While in some instances they have lower sensitivity than state of the art sensors; they have the ability to measure large ranges of torsion and strain and have an advantageous fiber shape that can conform to a variety of complex surfaces.

While the methods and systems have been described in connection with preferred embodiments and specific examples, it is not intended that the scope be limited to the particular embodiments set forth, as the embodiments herein are intended in all respects to be illustrative rather than restrictive.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

Throughout this application, various publications are referenced. The disclosures of these publications in their entireties are hereby incorporated by reference into this application in order to more fully describe the state of the art to which the methods and systems pertain.

It will be apparent to those skilled in the art that various modifications and variations can be made without departing from the scope or spirit. Other embodiments will be apparent to those skilled in the art from consideration of the specification and practice disclosed herein. It is intended that the specification and examples be considered as exemplary only, with a true scope and spirit being indicated by the following claims.

1. A flexible stretchable sensor comprising:
a plurality of flexible and stretchable fibers in close proximity to one another, wherein each of the flexible fibers comprises a hollow electrically insulating elastomeric fiber at least partially filled with a flexible and stretchable conductive material and an electrical connector in electrical communication with the flexible and stretchable conductive material,
wherein a change in an electrical parameter of at least one of the plurality of flexible and stretchable fibers is used to sense an event associated with the at least one of the plurality of flexible and stretchable fibers.

2. The flexible stretchable sensor of claim 1, wherein the plurality of flexible and stretchable fibers in close proximity to one another comprises at least two flexible and stretchable fibers twisted together.

3. The flexible stretchable sensor of claim 1, wherein the change in the electrical parameter of the at least one of the plurality of flexible and stretchable fibers comprises a change in capacitance of the at least one of the plurality of flexible and stretchable fibers is used to sense a change in torsion or a change in strain of the at least one of the plurality of flexible and stretchable fibers or the change in capacitance of the at least one of the plurality of flexible and stretchable fibers is used to sense a touch to the at least one of the plurality of flexible and stretchable fibers.

4. The flexible stretchable sensor of claim 3, wherein the change in capacitance of the at least one of the plurality of flexible and stretchable fibers used to sense the change in torsion or the change in strain is caused by a change in a geometry of the at least one of the plurality of flexible and stretchable fibers.

5. The flexible stretchable sensor of any of claim 3, wherein the change in capacitance of the at least one of the plurality of flexible and stretchable fibers used to sense the touch to the at least one of the plurality of flexible and stretchable fiber is caused by the touch.

6. The flexible stretchable sensor of claim 3, wherein torsion can be measured up to 10,800 rad/m or greater.

7. The flexible stretchable sensor of claim 3, wherein strain can be measured at 100 percent or greater increase in length of the plurality of flexible and stretchable fibers in close proximity to one another.

8. The flexible stretchable sensor of claim 1, wherein the plurality of flexible and stretchable fibers in close proximity to one another have a length, said length divided into a plurality of sections, wherein a change in capacitance in one or more of the plurality of flexible and stretchable fibers in close proximity to one another can be used to sense a touch to one or more of the plurality of flexible and stretchable fibers in close proximity to one another and to determine a specific section of the plurality of sections where the touch occurred.

9. The flexible stretchable sensor of claim 2, wherein the at least two flexible and stretchable fibers twisted together have a length, said length divided into at least two sections, wherein a first of the at least two flexible and stretchable fibers twisted together has the flexible and stretchable conductive material in a first and a second section of the at least two sections and a second of the at least two flexible and stretchable fibers twisted together has the flexible and stretchable conductive material in only a first section of the at least two sections and wherein a touch can be sensed and determined to be in the first section by a change in capacitance of the first and the second of the at least two flexible and stretchable fibers twisted together and a touch can be detected and determined to be in the second section by a change in capacitance of the first of the at least two flexible and stretchable fibers twisted together.

10. The flexible stretchable sensor of claim 1, wherein the plurality of flexible and stretchable fibers in close proximity to one another comprise at least three flexible and stretchable fibers twisted together and having a length, said length divided into at least three sections, wherein a first of the at least two flexible and stretchable fibers twisted together has the flexible and stretchable conductive material in a first, a second, and a third section of the at least three sections and a second of the at least three flexible and stretchable fibers twisted together has the flexible and stretchable conductive material in only the first section and the second section of the at least three sections and a third of the at least three flexible and stretchable fibers twisted together has the flexible and stretchable conductive material in only the first section of the at least three sections, wherein a touch can be sensed and determined to be in the first section by a change in capacitance of the first, the second and the third of the at least three flexible and stretchable fibers twisted together and a touch can be detected and determined to be in the second section by a change in capacitance of only the first and the second of the at least three flexible and stretchable fibers twisted together and a touch can be detected and determined to be in the third section by a change in capacitance of only the first of the at least three flexible and stretchable fibers twisted together.

11. The flexible stretchable electrical sensor of claim 1, wherein the plurality of flexible and stretchable fibers each have a triangular cross-section.

12. The flexible stretchable electrical sensor of claim 11, wherein the hollow electrically insulating elastomeric fiber has a wall thickness of approximately 55 μm to approximately 160 μm and the triangular cross-section has a side length of approximately 235 μm to approximately 850 μm.

13. A flexible stretchable sensor comprising:
at least two flexible and stretchable fibers having a length, said fibers helically twisted together substantially throughout the length, wherein each of the flexible fibers comprises:
a hollow electrically insulating elastomeric fiber at least partially filled with a flexible and stretchable conductive material; and
an electrical connector in electrical communication with the flexible and stretchable conductive material,
wherein a change in capacitance can be measured at the electrical connector of each of the at least two flexible and stretchable fibers, said change in capacitance caused by a change in strain or torsion to at least a portion of the length of the at least two flexible and stretchable fibers.

14. The flexible stretchable sensor of claim 13, wherein the change in capacitance of the at least two flexible and stretchable fibers caused by the change in the strain or torsion to the portion of the length of the at least two flexible and stretchable fibers is caused by a change in a geometry of the at least two flexible and stretchable fibers.

15. The flexible stretchable sensor of claim 14, wherein the change in a geometry of the at least two flexible and stretchable fibers comprises increasing a contact area between the two flexible and stretchable fibers, resulting in increased capacitance.

16. The flexible stretchable sensor of claim 13, wherein strain can be measured up to a 100 percent increase in the length of the at least two flexible and stretchable fibers.

17. (canceled)

18. (canceled)

19. The flexible stretchable sensor of claim 13, wherein torsion can be measured up to 10,800 rad/m or greater.

20. A flexible stretchable touch sensor comprising:
at least two flexible and stretchable fibers having a length helically twisted together substantially throughout the length, wherein each of the flexible fibers comprises:
a hollow electrically insulating elastomeric fiber at least partially filled with a flexible and stretchable conductive material; and
an electrical connector in electrical communication with the flexible and stretchable conductive material,
wherein said length is divided into at least two sections, wherein a first of the at least two flexible and stretchable fibers twisted together has the flexible and stretchable conductive material in a first and a second section of the at least two sections and a second of the at least two flexible and stretchable fibers twisted together has the flexible and stretchable conductive material in only a first section of the at least two sections and wherein a touch can be sensed and determined to be in the first section by a change in capacitance of the first and the second of the at least two flexible and stretchable fibers twisted together as measured at the electrical connectors of the first and the second of the at least two flexible and stretchable fibers and a touch can be detected and determined to be in the second section by a change in capacitance of the first of the at least two flexible and stretchable fibers twisted together as measured at the electrical connector of the first of the at least two flexible and stretchable fibers.

21. The flexible stretchable touch sensor of claim 20, wherein the change in capacitance of the at least two flexible and stretchable fibers used to sense the touch is caused by the touch.

22. A method of capacitive sensing, comprising:
providing a plurality of flexible and stretchable fibers in close proximity to one another, said plurality of flexible and stretchable fibers having a length, wherein each of the flexible fibers comprises a hollow electrically insulating elastomeric fiber at least partially filled with a flexible and stretchable conductive material and an electrical connector in electrical communication with the flexible and stretchable conductive material; and
sensing a change in capacitance of at least one of the plurality of flexible and stretchable fibers in close proximity to one another, wherein the change in capacitance is cause by at least one of a change in torsion to at least a portion of the length of the at least one of the plurality of flexible and stretchable fibers, a change in strain to at least a portion of the length of the at least one of the plurality of flexible and stretchable fibers, or at touch to at least one of the plurality of flexible and stretchable fibers.

23. A method of sensing using a flexible stretchable strain sensor, comprising:
providing at least two flexible and stretchable fibers having a length;
helically twisting the at least two flexible and stretchable fibers together substantially throughout the length, wherein each of the flexible fibers comprises a hollow electrically insulating elastomeric fiber at least partially filled with a flexible and stretchable conductive material, and an electrical connector in electrical communication with the flexible and stretchable conductive material; and
detecting, at the electrical connectors of each of the at least two flexible and stretchable fibers, a change in capacitance caused by a change in strain or torsion to at least a portion of the length of the at least two flexible and stretchable fibers.

24. The method of claim 23, wherein the change in capacitance of the at least two flexible and stretchable fibers caused by the change in the strain or torsion to the portion of the length of the at least two flexible and stretchable fibers is caused by a change in a geometry of the at least two flexible and stretchable fibers.

25. The method of claim 24, wherein the change in a geometry of the at least two flexible and stretchable fibers comprises increasing a contact area between the two flexible and stretchable fibers, resulting in increased capacitance.

26. The method of claim 23, wherein strain can be measured up to a 100 percent increase in the length of the at least two flexible and stretchable fibers.

27. (canceled)

28. (canceled)

29. The method of claim 23, wherein torsion can be measured up to 10,800 rad/m or greater.

30. A method of sensing touch using a flexible stretchable touch sensor, comprising:
providing at least two flexible and stretchable fibers having a length in close proximity substantially throughout the length, wherein each of the flexible fibers comprises a hollow electrically insulating elastomeric fiber at least partially filled with a flexible and stretchable conductive material, and an electrical connector in electrical communication with the flexible and stretchable conductive material;
dividing said length into at least two sections, wherein a first of the at least two flexible and stretchable fibers has the flexible and stretchable conductive material in a first and a second section of the at least two sections and a second of the at least two flexible and stretchable fibers has the flexible and stretchable conductive material in only a first section of the at least two sections; and
sensing a touch and determining the touch is in the first section by measuring a change in capacitance of both the first and the second of the at least two flexible and stretchable fibers; or
sensing the touch and determining the touch is in the second section by measuring a change in capacitance of only the first of the at least two flexible and stretchable fibers.

31. (canceled)

32. (canceled)

33. (canceled)

34. (canceled)

35. (canceled)

36. (canceled)

37. (canceled)

38. (canceled)

39. (canceled)
